(19) United States
(12) Patent Application Publication
(10) Pub. No.: US 2026/0323847 A1
(43) Pub. Date: Oct. 15, 2026

(54) MRI ENCLOSURE AND SYSTEM FOR MOUNTING A DISPLAY THERETO

(71) Applicant: GE Precision Healthcare LLC, Waukesha, WI (US)

(72) Inventors: Michael E. Smith, Whitewater, WI (US); Jeff Johnson, Greenfield, WI (US); Adam Pautsch, Oconomowoc, WI (US); Bai Xuan, Beijing (CN)

(73) Assignee: GE Precision Healthcare LLC, Waukesha, WI (US)

(21) Appl. No.: 19/175,456

(22) Filed: Apr. 10, 2025

(51) Int. Cl. H05K 5/02; G01R 33/54; H05K 5/00

(52) U.S. Cl. CPC H05K 5/0204; G01R 33/546; H05K 5/0018; H05K 5/0217

(57) ABSTRACT

A system for mounting a display to an MRI system enclosure comprises a base frame configured to connect to a front panel of the MRI system enclosure, the base frame having a back plate and four sidewalls extending perpendicular from the back plate so as to define a cavity configured to house a back side of the display. The system includes a front bezel with an opening configured to surround the display, wherein the front bezel covers the base frame and contacts the front panel of the MRI system enclosure. The front bezel and the base frame are configured to connect together by at least one interlocking joint to retain the front bezel around the display, wherein each of the at least one interlocking joint is formed by a first joint feature on one of the four sidewalls that removably mates with a second joint feature on the front bezel.

### BACKGROUND

The present disclosure generally relates to enclosures for magnetic resonance (MR) imaging systems and other patient imaging systems, and specifically to systems for removably mounting a display device thereto.

MR imaging (MRI) has proven useful in diagnosis of many diseases. MRI provides detailed images of soft tissues, abnormal tissues such as tumors, and other structures, which cannot be readily imaged by other imaging modalities. Further, MRI operates without exposing patients to ionizing radiation experienced in modalities such as CT and xrays. MRI is often used to obtain internal physiological information about a patient, including for brain imaging, thoracic imaging, spine imaging, cardiac imaging, and imaging other sections or tissues within a patient’s body (anywhere on the patient). Additionally, many MRI systems enable multi-physiology or whole body imaging where a substantial portion of the patient’s body is imaged, which is typically performed by separately imaging several portions of the patient’s body and then stitching the images together to generate one continuous image. Other gantry-based imagers include computed tomography (CT) systems, positron emission tomography (PET) systems, single photon emission computed tomography (spect) systems, and the like.

### SUMMARY

This Summary is provided to introduce a selection of concepts that are further described below in the Detailed Description. This Summary is not intended to identify key or essential features of the claimed subject matter, nor is it intended to be used as an aid in limiting the scope of the claimed subject matter.

In one aspect of the disclosure, a system for mounting a display to an imager enclosure, such as a magnetic resonance imaging (MRI) system enclosure, includes a base frame and a front bezel. The base frame is configured to connect to a front panel of the enclosure, the base frame having a back plate configured to contact the front panel and four sidewalls extending perpendicular from the back plate. The back plate and the four sidewalls define a cavity configured to house a back side of the display. The front bezel has an opening configured to surround the display, wherein the front bezel covers the base frame and has a surrounding edge that contacts the front panel of the enclosure. The front bezel and the base frame are configured to connect together by at least one interlocking joint to retain the front bezel around the display, wherein each of the at least one interlocking joint is formed by a first joint feature on one of the four sidewalls that removably mates with a second joint feature on the front bezel.

In one embodiment, the first joint feature is a channel on an outer face of each of at least two opposing sidewalls of the four sidewalls of the base frame and the second joint feature is a protrusion on each of at least to opposing inward-facing sides of the front bezel, wherein the channel and the protrusion are configured to snuggly fit together to retain the front bezel around the display and over the base frame.

Optionally, the protrusion is a semi-circular convex section on the front bezel and the channel is a semi-circular concave section on the outer face the sidewall of the base frame.

In another embodiment, the first joint feature is a protrusion on an outer face of each of at least two opposing sidewalls of the four sidewalls of the base frame and the second joint feature is a channel on each of at least to opposing inward-facing sides of the front bezel, wherein the channel and the protrusion are configured to snuggly fit together to retain the front bezel around the display and over the base frame.

In one embodiment, the system includes at least two interlocking joints on opposing sidewalls.

In another embodiment, the system includes at least one interlocking joint on each of the four sidewalls surrounding the display.

In still another embodiment, the system includes at least two interlocking joints on each of the four sidewalls surrounding the display.

In one embodiment, the front bezel comprises a front ring configured to surround a front face of the display and a flange that is perpendicular to the front ring, wherein the second joint feature is a protrusion is on an inward facing side of the flange and the first joint features is a channel is on an outer face of each of the at least two sidewalls of the base frame.

Optionally, the flange is configured to deflect outward as the protrusion slides past a detent on the outer face of each of the at least two sidewalls of the base frame.

In one embodiment, the protrusion is a semi-circular convex section on the flange and the channel is a semi-circular concave section on the outer face of the sidewall of the base frame.

In one embodiment, the front panel has an indentation and the base frame is configured to fit within the indentation in the front panel such that a gap remains between an outer face of each of the sidewall of the base frame and an inner face of the indentation. The flange on at least one of the sidewalls is configured to slide between the outer face of the sidewall of the base frame and the inner face of the indentation when the front bezel connects to the base frame.

In one embodiment, the front bezel is configured such that a front ring around the display is flush with the front face of the display when the protrusion of the front bezel is in the channel.

In one embodiment, the front bezel further comprises a keypad portion configured to surround a keypad configured to provide control inputs for the MRI system, wherein the keypad portion is below the display ring portion. The base frame further comprises a keypad mount to mount the keypad below the display.

In another embodiment, the front bezel further comprises at least one fork clasp positioned to clasp around at least one tubular knob attached to the front panel.

In another aspect of the present disclosure, magnetic resonance imaging (MRI) system or other gantry-based patient imaging system includes an enclosure comprising a front panel defining a circular opening of a bore in which a patient is imaged, a display, a keypad, and a mounting system configured to mount the keypad and the display to the front panel of the enclosure. The mounting system includes a base frame configured to connect to the front panel of the enclosure. The base frame comprises a back plate configured to contact the front panel and four sidewalls surrounding the back plate, wherein the back plate and the four sidewalls define a cavity configured to house a back side of the display. The base frame further comprises a keypad mount to mount the keypad below the display and a front bezel with a display opening configured to surround the display and a keypad opening configured to surround the keypad. The front bezel and the base frame are configured to connect together by at least one interlocking joint to retain the front bezel around the display, wherein each of the at least one interlocking joint is formed by a channel on one of the four sidewalls that removably mates with a protrusion on the front bezel, wherein the channel and the protrusion are configured to fit together to retain the front bezel around the display and over the base frame.

Various other features, objects, and advantages of the invention will be made apparent from the following description taken together with the drawings.

### BRIEF DESCRIPTION OF THE DRAWINGS

The present disclosure is described with reference to the following Figures.

FIG. 1 illustrates an exemplary MRI system having an enclosure according to one embodiment of the present disclosure.

FIG. 2 illustrates one embodiment of a front panel of an MRI enclosure showing an exploded view of a mounting system for a display according to one embodiment of the present disclosure.

FIGS. 3A and 3B show perspective views of an exemplary mounting system assembled together with a display and keypad and shown separated from the MRI enclosure.

FIGS. 4A and 4B show different exploded views of a display being assembled to one embodiment of a base frame of the disclosed mounting system.

FIGS. 5A and 5B show one embodiment of a front bezel of the disclosed mounting system.

FIG. 6 shows the mounting system of FIGS. 3A and 3B assembled to an MRI enclosure.

FIGS. 7A and 7B are cross-section views of the assembled mounting system of FIG. 6 showing a connection arrangement between the front bezel and the base frame.

FIG. 8 is an exploded view of the assembled mounting system of FIG. 6 with the front bezel removed and rotated showing a connection arrangement between the front bezel and the front panel of the MRI enclosure.

### DETAILED DESCRIPTION

In the present description, certain terms have been used for brevity, clarity and understanding. No unnecessary limitations are to be inferred therefrom beyond the requirement of the prior art because such terms are used for descriptive purposes only and are intended to be broadly construed.

As used herein, unless otherwise limited or defined, discussion of particular directions is provided by example only, with regard to particular embodiments or relevant illustrations. For example, discussion of “top,” “bottom,” “front,” “rear,” “left,” “right,” “horizontal,” “vertical,” and “longitudinal” features and/or relative motion, e.g., movement “up” and “down,” is generally intended as a description only of the orientation of such features relative to a reference frame of a particular example or illustration. Correspondingly, for example, a “top” feature may sometimes be disposed below a “bottom” feature (and so on), in some arrangements or embodiments. Additionally or alternatively, embodiments may be arranged in a different orientation such that “top” and “bottom” features are arranged horizontally relative to each other, for example in a “left-to-right” orientation.

The use herein of the terms “including,” “comprising,” or “having,” and variations thereof, is meant to encompass the elements listed thereafter and equivalents thereof, as well as additional elements. Embodiments recited as “including,” “comprising,” or “having” certain elements are also contemplated as “consisting essentially of” and “consisting of” those certain elements.

The inventors have recognized that improved systems are needed for mounting and securing a display and/or keypad of a user interface to an enclosure of a gantry-based patient imaging system, the enclosure of the MRI system. The enclosure shown herein is an MRI enclosure. In other embodiments, the disclosed mounting system could be utilized to mount the display to an enclosure of a different gantry-based imager in which a patient gets positioned, such as a CT imaging system, a PET imaging system, a SPECT imaging system, or the like. The display and/or keypad are part of the user interface for controlling and monitoring the function of the MRI system, such as for inputting control commands and/or viewing settings, sensed parameters, and operating states of the MRI system. The keypad may also be used for controlling automatic table motion (table up/down, cradle in/out, return to home position, etc.) and workflow functions such as landmarking. Displays on MRI systems fail and need updating, and thus the mounting systems for the displays and associated user interfaces need to allow easy access and removal. The inventors have recognized that current mounting systems make it difficult to access and service the display. Existing systems, for example, mount the displays behind the front panel of the MRI enclosure, and thus require removal of the entire front panel of the enclosure to access the display, which is cumbersome and time-consuming. Moreover, the inventors have recognized that the display mounting system needs to withstand the significant vibrations of the MRI system when operating to image a patient, as well as needing to be cleanable to meet and exceed infection control standards for a healthcare environment.

Additionally, the inventors endeavored to create a modular mounting system for the user interface that enables connection of multiple different display devices to the MRI enclosure to facilitate customization and/or modernization of the user interface system over time. Moreover, the inventors endeavored to develop a mounting system that provides easy access to and removal/reconnection of the display, including providing toolless connections at many or most steps so as to minimize technician time and the need for specialty tools.

The disclosed mounting system is a two-piece mounting system that connects to the front panel of the MRI enclosure and holds the display thereto. The disclosed mounting system comprises a base frame configured to connect to the front panel of the MRI enclosure and to mount the display and keypad thereto. Once mounted, a front bezel snaps into place over the top of the base frame, wherein the surrounding edges of the front bezel tightly abut the front panel, the display, and the keypad, providing a smooth continuous look of the enclosure with minimized gaps at the seams for cleanability and prevention of liquid ingress. The two-piece mounting system provides a modular means for mounting the display to the exterior of the MRI enclosure that is secure, easy to service with toolless connections (other than where may be required by regulations), and cleanable to meet infection control standards in a healthcare environment.

The base frame is configured to connect to a front panel of the MRI system enclosure, such as being screwed or bolted thereto so as to provide a semi-permanent connection. The base frame includes a back plate configured to contact the front panel and four sides surrounding the back plate. The back plate and the four sides define a cavity configured to house a back side of the display. In some embodiments, an inner face of each of the four sides of the base frame engages a housing of the display. Most or all of the base frame is configured to remain in place during servicing of the display. However, in some implementations, at least a portion of one of the four sides of the base frame is removably attached to the remainder of the base frame and is configured to be removed to enable removal and replacement of the display. In one embodiment of the base frame disclosed herein includes a removable side panel configured to be removed during servicing to enable access to the back of the display and/or flexibility to accommodate different display enclosures. Thus, various display and keypad sizes can be mounted using the base frame, or the keypad can be eliminated, and the only part of the enclosure that would need to be redesigned would be the bezel.

The front bezel has a display opening configured to surround the display and some embodiments also have a keypad opening configured to surround the keypad. The front bezel mates with the front panel of the MRI enclosure and provides a finished look and smooth transition that provides the appearance of housing the display within the front panel of the MRI enclosure. The front bezel is configured to removably connect to at least two of the four sides of the base by an interlocking joint and removably connect to the front panel of the MRI system enclosure. The front bezel snaps into place onto the front panel and over the base frame by connection of the at least one interlocking joint. In some embodiments, the system includes at least two interlocking joints, at least one on each of two opposing sides. Each interlocking joint may comprise a channel and a protrusion that fits in the channel, wherein the protrusion and the channel are inversely shaped such that they fit snuggly together and tightly retain the front bezel to the base frame. In one embodiment, the protrusion is a semi-circular convex section and the channel is a semi-circular concave section that fits snuggly around the semi-circular protrusion, wherein the semi-circular arrangement provides two smoothly sloped sides that facilitates sliding the front bezel into place on the based frame and also disconnecting it therefrom.

The protrusion is on either an outer face of a side of the base frame or on the inner face of the front bezel that makes contact with the outer face; the channel is oppositely positioned such that the protrusion is in the channel when the front bezel is correctly placed. In one implementation, each of at least two opposing sides of the base frame has at least one channel configured to receive a respective protrusion on the front bezel to retain the front bezel around the display, over the base frame, and against the front panel. In an alternative implementation, each of at least two opposing sides of the base frame has a protrusion configured to fit into a channel on the front bezel to retain the front bezel around the display, over the base frame, and against the front panel.

In some embodiments, the front bezel comprises a front ring configured to surround a front face of the display, such as to be flush with the front face of the display and abut tightly thereto. A flange extends perpendicularly inward from the front ring. The protrusion/channel (depending on which way the interlocking joint is arranged) is on an inward facing side of the flange and the channel/protrusion (whichever side of the interlocking joint is not on the flange) is on an outer face of each of the at least two sides of the base frame such that the protrusion is forced into the channel when the front bezel is slid into place over the base frame. The flange is configured to deflect outward as the protrusion slides past a detent (e.g., on the outer face of each of the at least two sides of the base frame). In one embodiment, the protrusion is a semi-circular convex section on the flange and the channel is a semi-circular concave section on the outer face of each of the at least two sides of the base frame, wherein the semi-circular arrangement provides two smoothly sloped sides that facilitates sliding the front bezel into place on the based frame and also disconnecting it therefrom.

The interlocking joint provides a solid connection of the front bezel to the base frame that secures it tightly around the display and is toolless. In some embodiments, the system may comprise at least one interlocking joint on each of the four sides surrounding the display. In such an embodiment, all of the four sides of the base frame have at least one channel/protrusion configured to receive a corresponding protrusion/channel on the front bezel. In some embodiments, each of at least two of the sides of the base frame have two or more channels, each configured to receive a respective protrusion on the front bezel to removably secure the front bezel to the base frame and against the front panel of the MRI enclosure.

In some embodiments, one or more additional toolless connections may be located to secure the front bezel to the front panel of the MRI enclosure. For example, the front bezel may include at least one fork clasp positioned to clasp around at least one tubular protrusion attached to the front panel. Such additional toolless connection(s) may be located on the keypad portion of the front bezel, which is the area configured to surround the keypad. In one such embodiment, one or more fork clasps are positioned on a back side of the front bezel at or near the keypad portion. The fork clasps positioned to mate with and clasp around at least one tubular protrusion attached to the front panel of the front bezel surface to retain the keypad portion of the front bezel around the keypad and tightly mated against the front panel.

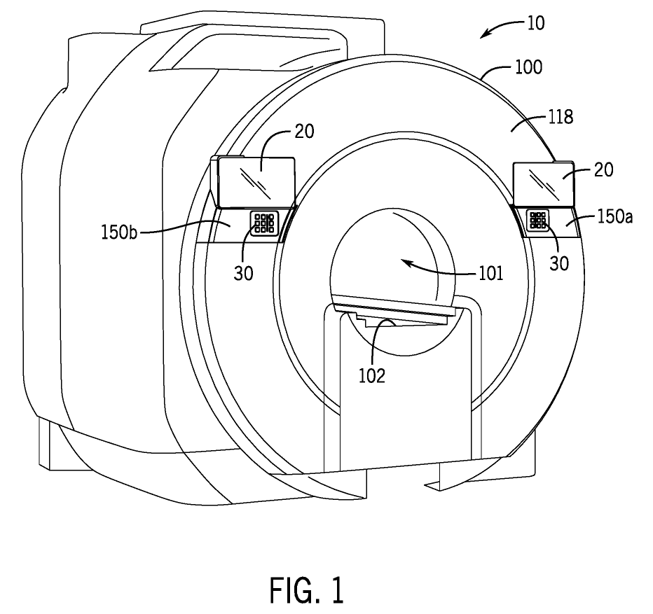

FIG. 1 shows an exemplary MRI system 10 having an enclosure 100 that provides and outer housing of the interior portions of the MRI system 10. The enclosure 100 encapsulates, for example, the magnets, power systems, cooling systems, gradient and sensing systems, controls and conducting systems, etc. for generating the MR image. The Enclosure 100 has a tubular shape surrounding a bore 101 in which a platform 102 is located to support a bed holding patient being imaged. The enclosure 100 has a front panel 118 that forms the front portion of the enclosure 100 at the entrance of the bore 101. The front panel 118 is configured to mount a user interface providing a means for interacting with the MRI system 10. The user interface includes a display 20, and in some embodiments also a keypad 30. A mounting system is configured to mount the display 20 and the keypad 30 to the front panel 118 and also to enable access to and removal thereof for servicing and replacement. In FIG. 1, the mounting system is assembled to the front panel 118 such that only the front surface of the front bezel 150 of the mounting system is visible, which provides a smooth and coherent look with the front panel 118 such that it gives the appearance of a unified piece.

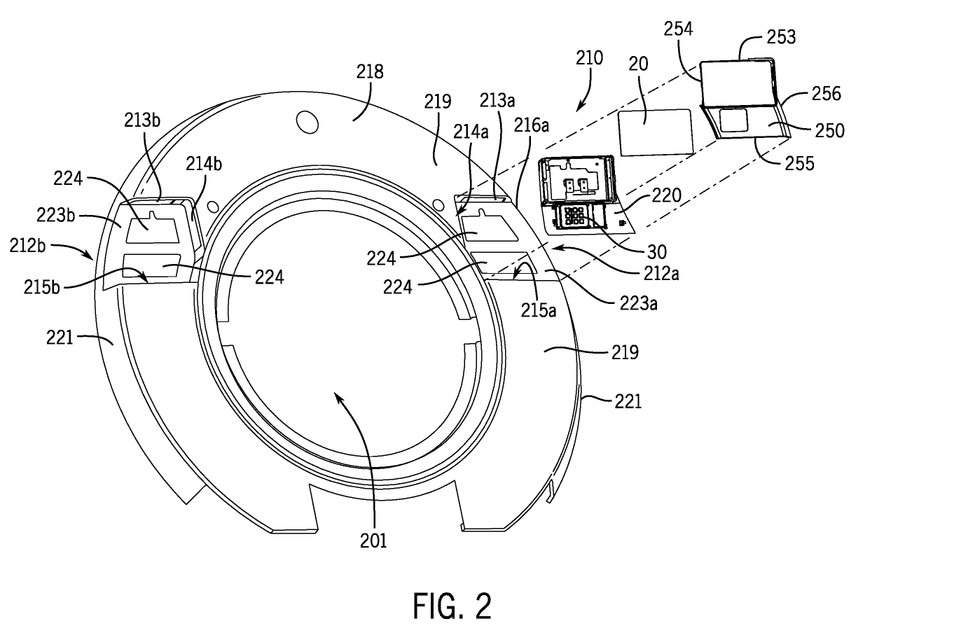

In the depicted embodiment, the MRI system 10 includes two displays 20 and a corresponding keypad 30 with each display 20, wherein a display is attached to the enclosure 100 on each of the right and left sides of the bore 101. A mounting system is configured to mount each display 20 and keypad 30, two front bezels 150a, 150b are configured to encapsulate the right and left displays, respectively. The right front bezel 150a is configured to mate with the right side of the front panel 118 and the left front bezel 150b is configured to make with the left side of the front panel 118. In some embodiments of the MRI system 10, only one user interface is included on the right side or the left side of the bore 101. In some implementations, the front panel is shaped to only enable connection of one or the other display (right or left). In other implementations, such as that shown in FIG. 2, the front panel is configured to enable connection of a display on either or both sides of the bore. In embodiments where only one display is connected, a flat front bezel may be provided to cover the section of the front panel 118, 218 where no display is connected.

FIG. 2 shows an exploded view of one embodiment of the mounting system 210 that includes a base frame 220 and a front bezel 250 configured to mount to a front panel 218. The front panel 218 is configured to mount a display 20 on each of the right and left sides of the bore 201. The front panel has indentations 212a and 212bon each of the right and left sides where respective mounting systems 210 can be attached. On a base face 223a, 223bof each indentation 212a, 212b, respectively, one or more cutouts 224 are provided through which cabling can be passed, such as for power and data to and from the display 20 and/or the keypad 30. In one embodiment, the base frame 220 and the front bezel 250 are each molded plastic pieces and are configured to mate together as described herein.

The right indentation 212a is configured to enable connection of a mounting system 210 on the right side. The right indentation 212ahas a top inner face 213a, a side inner face 214a, and a bottom inner face 215a that are configured to provide a cavity where a display and/or keypad are mounted to the front panel 218. The left indentation 212bis configured to enable connection of a mounting system (not shown) on the left side. The left indentation 212bhas a top inner face 213b, a side inner face 214b, and a bottom inner face 215b that are configured to provide a cavity where a display and/or keypad are mounted to the front panel 218 on the left side of the bore 210. FIGS. 2-8 show the mounting system for the right side, which is shaped to fit in the right indentation 212a. The left side mounting system (not shown for visual clarity) is shaped to fit in the left indentation 212b and is at least substantially a mirror image of the illustrated right side mounting system 210 (the display and/or keypad may be the same part number so some of the electrical ports may be the same on both side rather than mirrored). This design enables one display to be connected to either the right or left side, or for connection of two displays, one on each of the right and left sides of the bore 201.

The base frame 220 is configured to fit into the cavity formed by the indentations 212a, 212b. The display 20 and keypad 30 are then mounted to the base frame. The front bezel 250 is configured to be connected after the display 20 and the keypad 30 are connected and to attach in a toolless way to the based frame and/or the front panel 218. The outer edges 253, 254, and 255 of the front bezel 250 abut the inner faces 213a, 214a, 215a of the indentation 212a in the front panel 218 and the front bezel 250 is configured such that its front face is flush with the front face 219 of the front panel 218. The side edge 256 is shaped to abut and follow the shape of the outer edge 216a of the indentation 212a and positioned such that a side surface of the front bezel 250 is flush with the side 221 of the front panel 218.

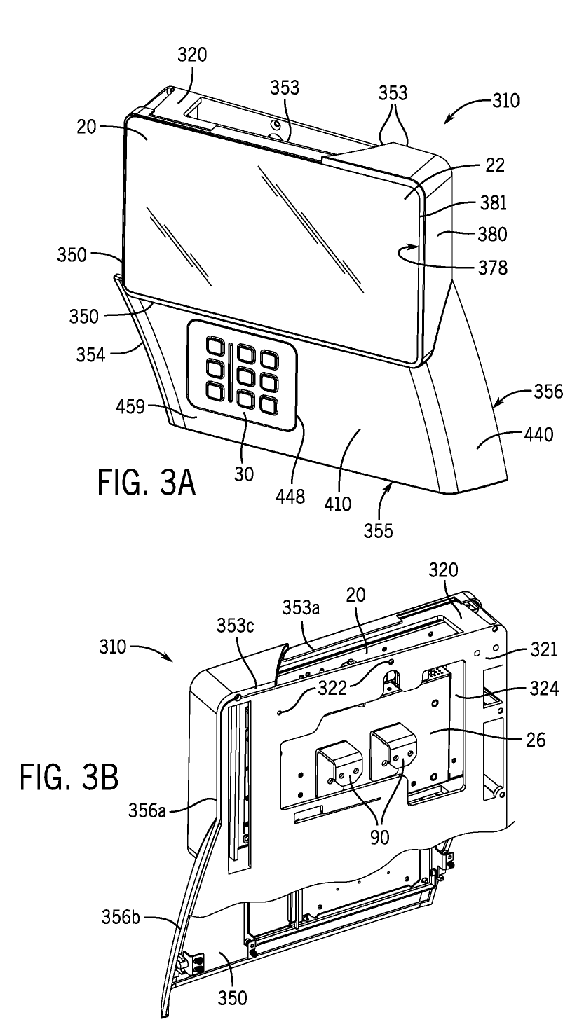

FIGS. 3A and 3B show front and back perspective views of an exemplary mounting system 310 for mounting a display to a front panel of an MRI system, showing the base frame 220 and the front bezel 250 assembled together around a display 20 and a keypad 30. The mounting system 310 is shown apart from the front panel so that the back side is visible. The mounting system 310 shown in the figures is configured to mount to the front panel on a right side of the bore, with a base frame 320 and a front bezel 350 configured to conform to the curvature on the right side. A left side mounting system of this configuration has a base frame 320 and front bezel 350 shaped to conform to the curvature of the front panel on a left side of the bore.

FIG. 3A shows a front perspective view of the assembled mounting system 310. The front bezel 350 comprises a display ring portion 380 configured to surround the display 20 and a keypad portion 410 configured to surround the keypad 30. A side portion 440 is configured to be flush with a side of the front panel (e.g., side 221 in FIG. 2). The display ring portion 380 includes a front ring 381 surrounding a display opening 378 configured to accommodate the front face 22 of the display 20. The keypad portion 410 base includes a keypad opening 448 configured to accommodate and surround the keypad 30. The front face 459 of the keypad portion 410 of the front bezel 350 is configured to be flush with the front panel (e.g., a front face 219 of the front panel 218 in FIG. 2).

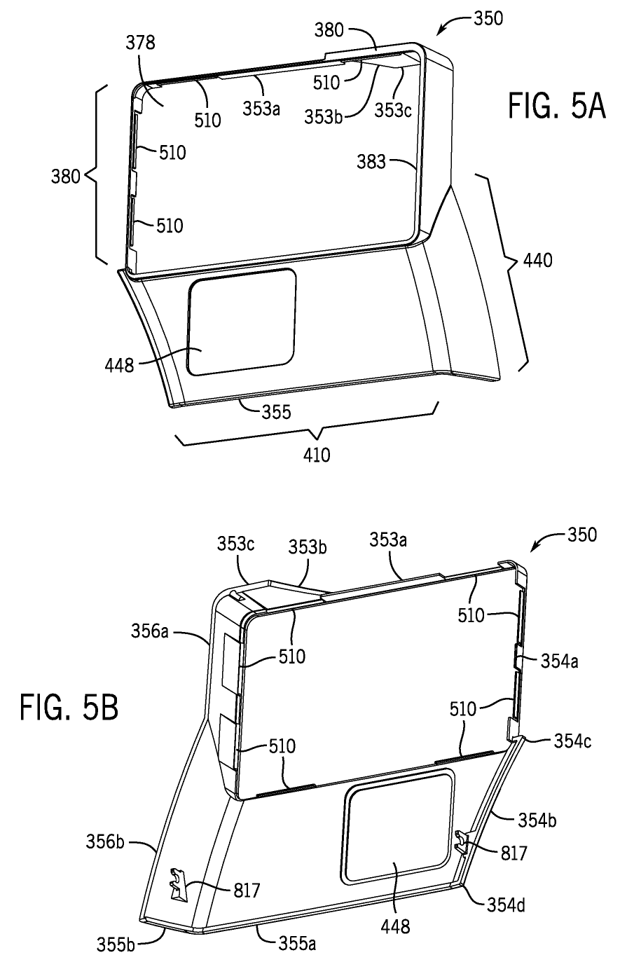

The front bezel 350 includes a surrounding edge configured to abut the front panel of the MRI enclosure. The surrounding edge includes a top edge 353, an inner side edge 354, a bottom edge 355, and an outer side edge 355. A more detailed view of the front bezel 350 is provided and discussed with respect to FIGS. 5A and 5B.

FIG. 3B shows a back perspective view of the assembled mounting system 310, which is shown apart from the front panel so that the back side is visible. The base frame 320 is configured to attach to the front panel, such as by screws, bolts, or other attachment means through holes 322 in the base frame 320. Specifically, a back side 321 of the base frame 320 is retained against the front panel (e.g., the base face 223a within the indentation 212aof the front panel 218 in FIG. 2). The base frame 320 includes one or more cutouts 324 through which cabling, connectors, etc. can be passed to connect to the display 20. Additionally, one or more hooks 90 may be connected to the backside 26 of the housing of the display 20. The hooks 90 are positioned to be passed through and slide within the at least one cutout 324. The hooks 90 are configured to hook to the base frame 320 to support the display in a support the display 20 during installation, such as to allow the display 20 to be tilted forward away from the base frame 320 to enable access to the back of the display during maintenance or installation (e.g., hung at a temporary location on or near the indentation 212a, 212b so the installer can use both hands to connect/disconnect the electrical connections). The hooks 90 are configured such that they are pushed into the cutout 324 once the display is installed against the base frame 320, and may also be placed so as not to interfere with the front panel (such as to be aligned with the cutout 224 in the front panel 218 in FIG. 2).

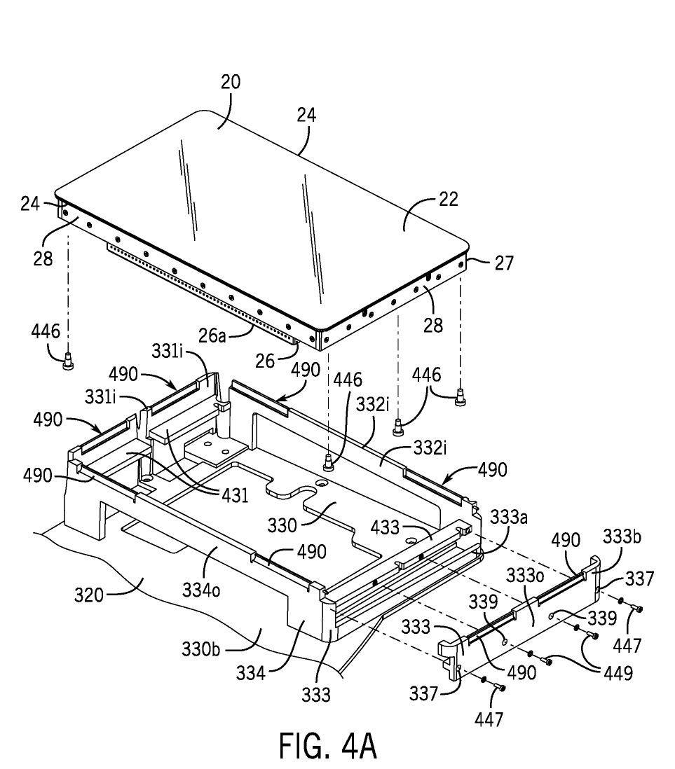

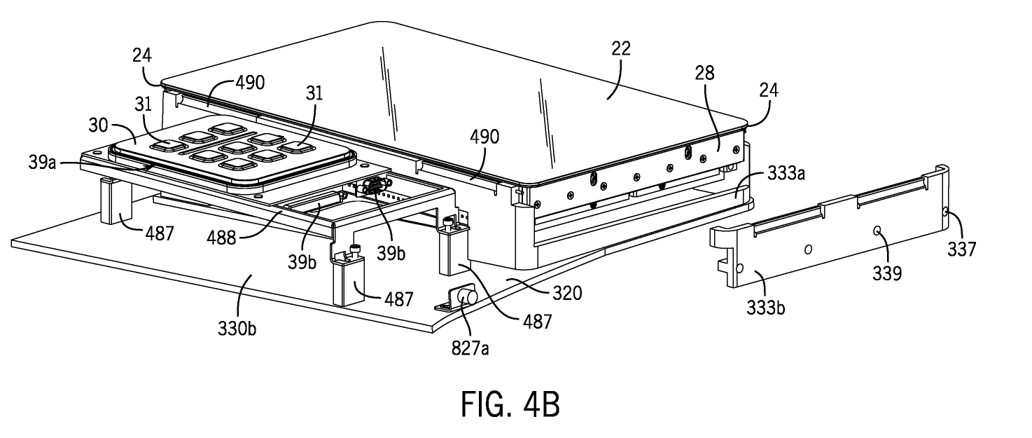

FIGS. 4A and 4B show exploded views of the base frame 320 and illustrate its connection to the display 20. The display 20 has a housing 27 with a front face 22, an outer edge 24 of the front face, four sides 28, and a back side 26. In the depicted embodiment, the display has an extended portion 26a of the back side. The base frame 320 includes a back plate 330 configured to be attached to the front panel of the MRI enclosure, as is described above. Four sidewalls 331-334 extend perpendicular from the back plate 330. The first lateral sidewall 331 is configured to contact the left side of the display housing 27. The top sidewall 332 is configured to contact a top side of the display housing 27. The bottom sidewall 334 is configured to contact a bottom side of the display housing 27. The second lateral sidewall 333 (comprised of parts 333a and 333b) is configured to contact the right side of the display housing 27. The second sidewall has two portions, including a stationary portion 333a and a removable portion 333b. The stationary portion 333a of the second sidewall and all of the other sidewalls 331, 332, and 334 are permanently connected to the base plate 330, such as molded as one unitary piece.

The back plate 330 and the sidewalls 331-334 form a cavity configured to receive and house a back side of the display 20. The inner faces of the sidewalls are configured to contact the sides 28 of the display housing 27 to retain it in place. The inner face 331i of the first lateral sidewall 331 and the inner face 332i of the top sidewall 322 are visible in FIG. 4A. The first sidewall 311 has a retaining bar 431 configured to support the back 26 of the display housing 27. Similarly, a retaining bar 433 is on the opposing side and also configured to support the back 26 of the display housing 27. The extended portion 26a of the back side is situated between the retaining bars 431 and 433 when the back of the display 20 is nested in the cavity created by the back plate 330 and the four sidewalls 331-334. As best seen in FIG. 4B, the side 28 of the housing 27 of the display 20 is situated against the inner faces of the four sidewalls 331-334 and the outer edge 24 of the front face 22 rests on the top edges of the four sidewalls 331-334.

Shoulder bolts 446 are configured to attach the back 26 of the display 20 to the retaining bar 433. Once the display 20 is stated and fixed within the cavity formed by the four sidewalls 331-334, the removable part 333b of the second lateral sidewall is fastened to the other sidewalls and thus to the display 20. In the depicted example, the outer screws 447 are placed through holes 337 to fasten the removable portion 333b of the lateral sidewall to the top sidewall 332 and the bottom sidewall 334. One or more middle screws 449 are passed through holes 339 in the center portion of the removable portion 333b to fasten it to the side 28 of the display.

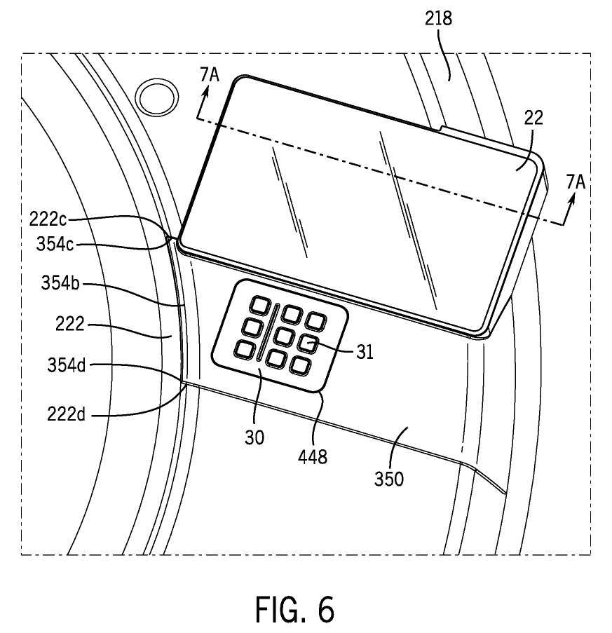

As shown in FIG. 4B, one or more keypad mounts 487 are located on a lower portion 330b of the back plate 330. The keypad mounts 487 may be, for example, stilts configured to support the keypad 30 at a position at which the it will be located in the keypad opening 448 of the front bezel once placed thereon (see also FIG. 6). Thus, the keys 31 of the keypad 30 are accessible once the front bezel 450 is assembled thereon. As shown in FIG. 4B, the keypad mounts 487 may attach to a support plate 488 on which a printed circuit board (pcb) 39a of the keypad 30 is mounted. Connectors 39b and other aspects of the keypad 30 may also be fastened to the support plate 488.

FIGS. 4A-5B and 7A-7B show one embodiment of an interlocking joint. In the embodiments shown, the protrusions are positioned on the front bezel and the channels are positioned on the based frame. The opposite arrangement, wherein the channels are on the front bezel and the protrusions are on the sidewalls of the base frame, is also contemplated and is within the scope of the present disclosure.

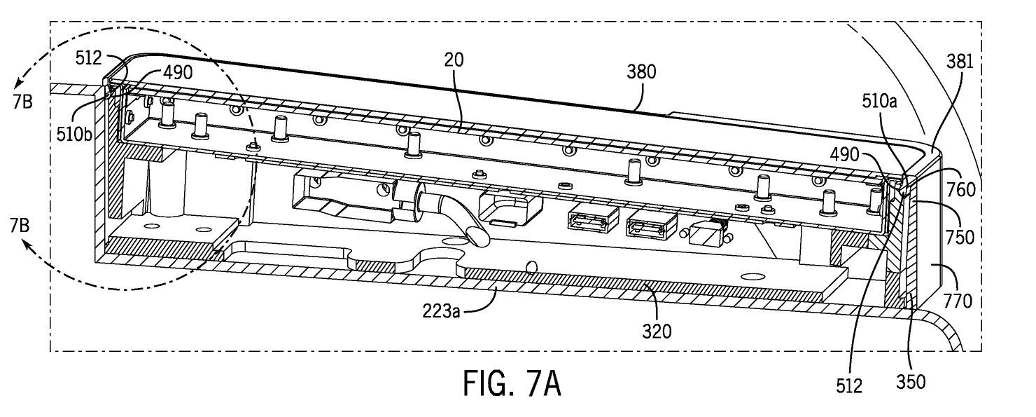

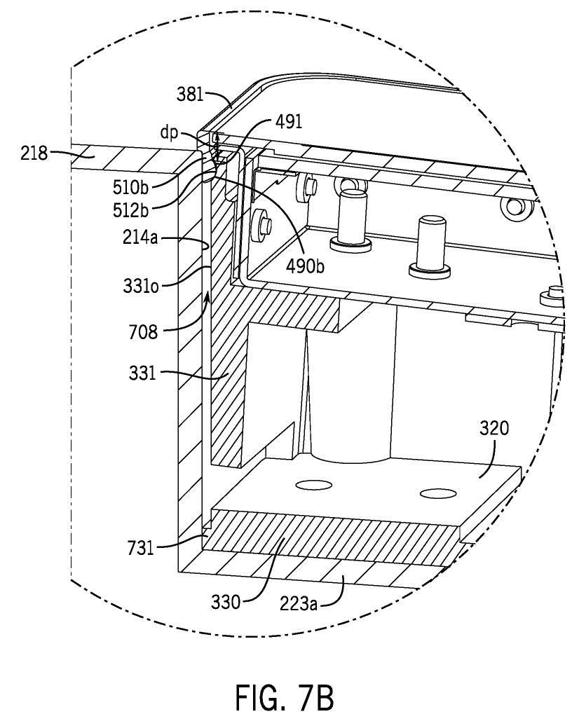

Returning to FIG. 4A, one embodiment of the interlocking joint is shown. A plurality of the walls have channels 490 configured to receive protrusions on the front bezel to removably fasten the front bezel thereto. Here, channels 490 are located on the outer faces of the sidewalls 331-334. The outer face 333o of the removable portion 333b and the outer face 334o of the bottom sidewall are visible in the figure. In the depicted example, all four of the sidewalls 331-334 have two channels 490, each configured to receive and mate with a respective protrusion on the front bezel. In the depicted embodiment, each channel 490 is about 5cm long. In other embodiments, each of the sidewalls 331-334 may have only one channel. In such an embodiment, each channel 490 may be approximately centered on each if the sidewalls 331-334 and may be longer than the embodiment shown, where each of the sidewalls 331-334 has two channels. In still other embodiments, only two of the sidewalls 331-334 may comprise one or more channels 490, such as two opposing sidewalls (i.e., the two lateral sidewalls 331 and 333, or the top and bottom sidewalls 332 and 334). The mating between the channels 490 and the front bezel is shown and described further with respect to FIGS. 7A and 7B.

FIGS. 5A and 5B show front and back perspective views of the front bezel 350 isolated from the rest of the system. As described above, the front bezel 350 comprises a display ring portion 380 with a display opening 378, a keypad portion 410 with a keypad opening 448, and a side portion 440.

The front bezel 350 includes a surrounding edge configured to abut the front panel of the MRI enclosure. As best seen in FIGS. 3B and 5B, the top edge 353 includes three portions, including a first top edge portion 353a configured to abut the front panel (e.g., the tope inner face 213ashown in FIG. 2), a second top edge portion 353b sloped to follow the front panel, where the display extends past the front face of the front panel (e.g., extending beyond the indentation 212a in FIG. 2), and a third top edge portion 353c is configured to extend to or beyond the side of the base frame. The outer edge 356 has a top portion 356aand a lower edge portion 356b. The tope edge portion 356aextends at least as deep as the base frame to visually cover it from the side view. The lower edge portion 356b and the edge portion 355b are part of the side portion 440 that extends over the side face 221 of the front panel 218 (see FIG. 2). The bottom edge portion 355a abuts the bottom inner face 215a of the indentation 212a in the front panel 218.

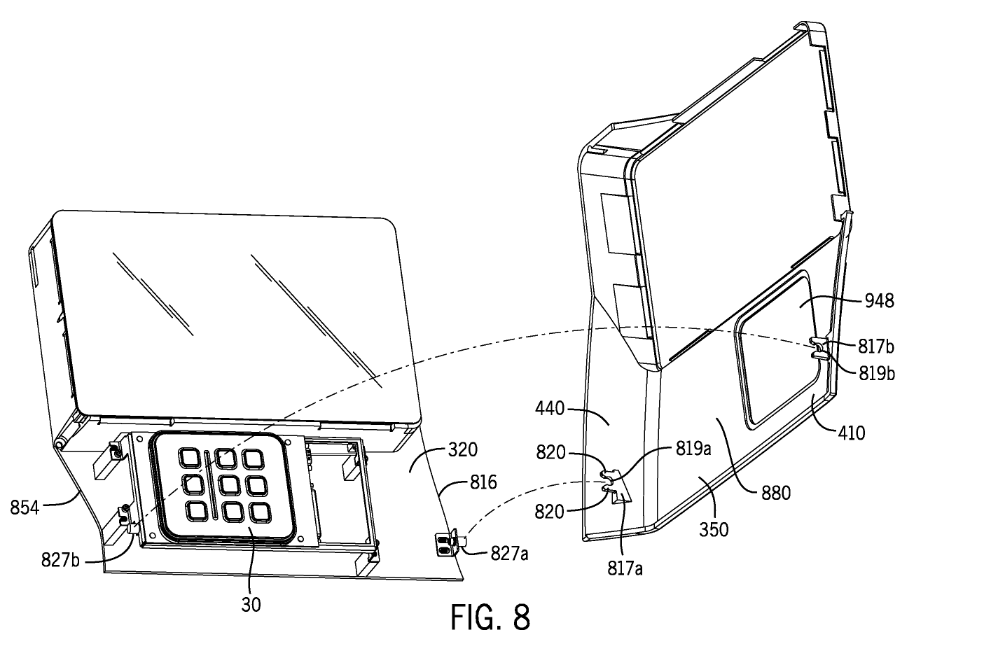

The inner side edge portion 354a is configured to abut the front panel 218 in the area of the indentation (e.g., the inner face 214aof the cavity). Referencing both FIGS. 5B and 8, the inner side edge portion 354b is curved and configured to follow the inner edge 222 of the front panel 218. The upper corner 354c of the inner side edge portion 354b is configured to meet the corner 222c of the inner edge 222 of the front panel 218. The lower corner 354dof the inner side edge portion 354b is configured to meet the lower corner 222d of the inner edge 222 of the front panel 218.

Referencing FIGS. 5A and 6, the display ring portion 380 of the front bezel 350 comprises the front ring 381 configured to surround the display 20 and to be flush with the front face 22 of the display 20. The inner edge 383 of the display ring portion 380 abuts the outer edge 24 (FIG. 4A) of the front face 22 of the display 20. As is better shown in the cross sections of FIGS. 7A and 7B, flanges 510 are configured to deflect as the front bezel 350 slides onto the base frame 320 to snap fit the two pieces of the interlocking joint together. Each side of the display ring portion 380 has at least one flange 510 that includes a protrusion 512 configured to fit within the channel 490 on the sidewall 331 of the base frame 320. On the outer side 770 of the display ring portion 380, the flange 510a is separated from a side 750 by an undercut 760 such that the flange 510a is separated from the side 750 and thus has room to deflect outward toward the side 750 as the front bezel 350 is connected to and disconnected from the base frame 320.

As labeled in FIG. 7B, a detent 391 is situated at the top of the channel 490. The flange 510 is configured to flex outward as the protrusion slides past the detent 491 on the outer face 331o of the sidewall 331. The flange 510b slides between the inner face 214a of the front panel 218 and the outer face 331o of the sidewall 331 of the base frame 320. The sidewall 331 is spaced apart from the inner face 214a by a lip 731 on the back plate 330, creating an air gap 708 between the outer face 331o of the sidewall 331 and the inner face 214a of the front panel 218. The flange 510b slides down into the air gap 708 and, as it does so, the flange 510b flexes such that the protrusion 512b fits into the channel 490b.

In the depicted embodiment, the protrusion 512b, is a semi-circular convex section on the flange 510b and the channel 490b is a semi-circular concave section on the outer face 331o the sidewall 331 of the base frame 320. In other embodiments, the protrusion 512, 512b may be on the sidewall 331-334 and the channel 490, 490b may be on the flange 510, 510b. The semi-circular arrangement provides two smoothly sloped sides that facilitates sliding the front bezel into place on the based frame and also disconnecting it therefrom. In other embodiments, the protrusion 512, 512b and the 490, 490b may be different corresponding shapes configured to facilitate a snap fit between the front bezel 250 and the base frame 320.

The flange 510 is short such that the mating surface is close to a top edge of the front ring 381 such that the mating surface secures the display ring portion 380 of the front bezel 350 tightly and securely around the display 22. For some implementations, the top edge of the protrusion 512b is positioned on the flange 510b just a short distance dp down from the top surface of the front ring 381, such as no more than 3/8 inch away from the top surface of the front ring 381. In the depicted embodiment, the distance d between the top edge of the front ring 381 and the top edge of the protrusion 512 is 3cm.

Additional connection means may be provided for toollessly securing the front bezel 350 to the base frame 320 and/or the front panel of the enclosure. FIG. 8 depicts a second connection means, which is a fork clasp 817a, 817b on a back side 880 of the front bezel 350, such as the back side 880 in the area of the keypad portion 410 and/or the side portion 440. Thereby, the keyboard portion 410 of the front bezel 350 is secured in place such that the keypad opening 448 is held tightly around the keypad 30. Each fork clasp 817a, 817b has two prongs 820 with a rounded clasp opening 819a, 819b therebetween and is configured to receive and clasp around a respective tubular knob 827a, 827b on the base plate of the base frame 320. Each tubular knob 827a, 827bmay be comprised of a soft material, such as a rubber or soft plastic, configured to be depressed as the prongs 820 of the fork clasp 817a, 817b pass over it. Alternatively, the tubular knob 827a, 827b may be comprised of a hard material, such as brass or other metal or a hard plastic, and the fork clasp 817a, 817b are configured to bend to deflect around the knobs during connection and disconnection. In the depicted embodiment, a first fork clasp 817a is on the side portion 440 of the front bezel 350 and is configured to receive the first tubular knob 827a so as to retain the side portion 440 to the outer edge 816 of the base plate 320. A second fork clasp 817b is on or near the keyboard portion 410 of the front bezel 350. The second tubular knob 827b is on or near the inner edge 854 of the base frame 320. Thus, the second fork clasp 817b is configured to retain the keyboard portion 410 to the inner edge 854 of the base plate 320 to retain the keypad portion 410 of the front bezel around the keypad 30.

This written description uses examples to disclose the invention(s), including the best mode, and also to enable any person skilled in the art to make and use the invention(s). Certain terms have been used for brevity, clarity, and understanding. No unnecessary limitations are to be inferred therefrom beyond the requirement of the prior art because such terms are used for descriptive purposes only and are intended to be broadly construed. The patentable scope of the invention(s) is defined by the claims and may include other examples that occur to those skilled in the art. Such other examples are intended to be within the scope of the claims if they have features or structural elements that do not differ from the literal language of the claims, or if they include equivalent features or structural elements with insubstantial differences from the literal languages of the claims.

What is claimed is:

1. A system for mounting a display to a magnetic resonance imaging (MRI) system enclosure, the system comprising:
a base frame configured to connect to a front panel of the MRI system enclosure, the base frame having a back plate configured to contact the front panel and four sidewalls extending perpendicular from the back plate;
wherein the back plate and the four sidewalls define a cavity configured to house a back side of the display;
a front bezel with an opening configured to surround the display, wherein the front bezel covers the base frame and has a surrounding edge that contacts the front panel of the MRI system enclosure;
wherein the front bezel and the base frame are configured to connect together by at least one interlocking joint to retain the front bezel around the display, wherein each of the at least one interlocking joint is formed by a first joint feature on one of the four sidewalls that removably mates with a second joint feature on the front bezel.

2. The system of claim 1, wherein the first joint feature is a channel on an outer face of each of at least two opposing sidewalls of the four sidewalls of the base frame and the second joint feature is a protrusion on each of at least to opposing inward-facing sides of the front bezel, wherein the channel and the protrusion are configured to fit together to retain the front bezel around the display and over the base frame.

3. The system of claim 2, wherein all of the four sidewalls of the base frame have at least one channel configured to receive a corresponding protrusion on the front bezel.

4. The system of claim 1, wherein the first joint feature is a protrusion on an outer face of each of at least two opposing sidewalls of the four sidewalls of the base frame and the second joint feature is a channel on each of at least to opposing inward-facing sides of the front bezel, wherein the channel and the protrusion are configured to fit together to retain the front bezel around the display and over the base frame.

5. The system of claim 1, wherein the front bezel has a display ring portion configured to surround the display.

6. The system of claim 5, wherein the display ring portion of the front bezel comprises a front ring configured to surround a front face of the display and a flange that is perpendicular to the front ring, wherein the second joint feature is a protrusion is on an inward facing side of the flange and the first joint features is a channel is on an outer face of the sidewall of the base frame.

7. The system of claim 6, wherein the flange is configured to deflect outward as the protrusion slides past a detent on the outer face of each of at least two of the four sidewalls of the base frame.

8. The system of claim 6, wherein the protrusion is a semi-circular convex section on the flange and the channel is a semi-circular concave section on the outer face of the sidewall.

9. The system of claim 6, wherein the protrusion is positioned on the flange less than 3/8 inch away from the front ring.

10. The system of claim 6, wherein the front panel has an indentation and wherein the base frame is configured to fit within the indentation in the front panel such that a gap remains between an outer face of each of the sidewall of the base frame and an inner face of the indentation;
wherein the flange on at least one of the sidewalls is configured to slide between the outer face of the sidewall of the base frame and the inner face of the indentation when the front bezel connects to the base frame.

11. The system of claim 6, wherein the front bezel is configured such that the front ring is flush with the front face of the display when the protrusion of the front bezel is in the channel.

12. The system of claim 5, wherein the front bezel further comprises a keypad portion configured to surround a keypad configured to provide control inputs for the MRI system, wherein the keypad portion is below the display ring portion.

13. The system of claim 12, wherein the base frame further comprises a keypad mount to mount the keypad below the display.

14. The system of claim 13, further comprising a fork clasp on a back side of the keypad portion and positioned to clasp around at least one tubular knob attached to the front panel of the front bezel surface to retain the keypad portion of the front bezel around the keypad.

15. The system of claim 1, wherein the front bezel further comprises at least one fork clasp positioned to clasp around at least one tubular knob attached to the front panel.

16. The system of claim 1, wherein an inner face of each of the four sidewalls of the base frame engages a housing of the display.

17. The system of claim 1, wherein at least a portion of one of the four sidewalls of the base frame is removably attached to a remainder of the base frame and is configured to be removed to enable removal and replacement of the display.

18. A magnetic resonance imaging (MRI) system comprising:
an enclosure comprising a front panel defining a circular opening of a bore in which a patient is imaged;
a display;
a keypad;
a mounting system configured to mount the keypad and the display to the front panel of the enclosure, the mounting system comprising:
a base frame configured to connect to the front panel of the enclosure, the base frame comprising:
a back plate configured to contact the front panel and four sidewalls surrounding the back plate, wherein the back plate and the four sidewalls define a cavity configured to house a back side of the display;
a keypad mount to mount the keypad below the display;
a front bezel with a display opening configured to surround the display and a keypad opening configured to surround the keypad; and
wherein the front bezel and the base frame are configured to connect together by at least one interlocking joint to retain the front bezel around the display, wherein each of the at least one interlocking joint is formed by a channel on one of the four sidewalls that removably mates with a protrusion on the front bezel, wherein the channel and the protrusion are configured to fit together to retain the front bezel around the display and over the base frame.

19. The system of claim 18, wherein the front bezel comprises a front ring configured to surround a front face of the display and a flange that is perpendicular to the front ring, wherein the protrusion is on an inward facing side of the flange and the channel is on an outer face of each of the sidewall of the base frame;
wherein the flange is configured to deflect outward as the protrusion slides past a detent on the outer face of the sidewall of the base frame.

20. The system of claim 19, the front panel has an indentation and wherein the base frame is configured to fit within the indentation in the front panel such that a gap remains between an outer face of the sidewall of the base frame and an inner face of the indentation;
wherein the flange on at least one of the sidewalls is configured to slide between the outer face of the sidewall of the base frame and the inner face of the indentation when the front bezel connects to the base frame.
